(19) United States
(12) Patent Application Publication
(10) Pub. No.: US 2002/0022149 A1
(43) Pub. Date: Feb. 21, 2002

(54) Organic electroluminescence element

(76) Inventors: Teruichi Watanabe, Tsurugashima-shi (JP); Shin Kawami, Tsurugashima-shi (JP); Takeo Wakimoto, Tsurugashima-shi (JP)

Correspondence Address: SUGHRUE, MION, ZINN, MACPEAK & SEAS, PLLC, 2100 PENNSYLVANIA AVENUE, N.W., WASHINGTON, DC, 20037-3213, US

(21) Appl. No.: 09/842,633

(22) Filed: Apr. 27, 2001

(30) Foreign Application Priority Data
Apr. 28, 2000 (JP) 2000-130693

(51) Int. Cl. B32B 9/00; B32B 19/00

(52) U.S. Cl. 428/690

(57) ABSTRACT

An organic electroluminescence element has a laminate of an anode, a hole injecting layer made of an organic compound and laminated, a light emitting layer made of an organic compound, an electron transport layer made of an organic compound, and a cathode. The light emitting layer includes a phosphorescent material. The hole injecting layer is made of a specific porphyrin compound.

### BACKGROUND OF THE INVENTION

1. Field of the Invention

The present invention relates to an organic electroluminescence element (hereinafter also referred to as the “organic EL element”) which utilizes the electroluminescence (hereinafter also referred to as the “EL”) of organic compounds which emit light in response to a current injected thereinto, and has a light emitting layer formed of a laminate of such materials.

2. Description of the Related Art

Generally, each of organic EL elements constituting a display panel using organic materials comprises an anode as a transparent electrode, a plurality of organic material layers including an organic light emitting layer, and a cathode comprised of a metal electrode, which are laminated as thin films in this order on a glass substrate as a display surface. The organic material layers include, in addition to the organic light emitting layer, a layer of a material having the hole transport capability such as a hole injecting layer, a hole transport layer or the like, a layer of a material having the electron transport capability such as an electron transport layer, an electron injecting layer, or the like. Organic EL elements comprising these layers have also been proposed. The electron injecting layer also contains an inorganic compound. As illustrated in FIG. 1, the organic EL element is comprised of a transparent anode 2; a hole transport layer 3 made of an organic compound; a light emitting layer 4 made of an organic compound; an electron transport layer 6 made of an organic compound; and a cathode 7 made of a metal, laminated on a transparent electrode 1 made of glass or the like.

When an electric field is applied to the laminate organic EL element including an organic light emitting layer and an electron or hole transport layer, holes are injected from the anode, at the same time electrons are injected from the cathode. The electrons and the holes are recombined in the organic light emitting layer to form excitons. The organic EL element utilizes light which is emitted when the excitons return to a ground state, i.e., the luminescence. Conventionally, a fluorescent material has been frequently used in the light emitting layer, and in some cases, a pigment may be doped into the light emitting layer, for improving the efficiency of light emission and stably driving the element.

In recent years, utilization of a phosphorescent material in the light emitting layer of the organic EL element has been proposed in addition to the fluorescent material (D. F. O'Brien and M. A. Baldo et al “Improved energy transfer in electrophosphorescent devices” Applied Physics letters Vol. 74 No. 3, pp 442-444, Jan. 18, 1999; M. A. Baldo et al “Very high-efficiency green organic light-emitting devices based on electrophosphorescence” Applied Physics letters Vol. 75 No. 1, pp 4-6, Jul. 5, 1999; Tetsuo Tsutsui et al “High quantum efficiency in organic light-emitting devices with Iridium-complex as a triplet emissive center” JJAP Vol. 38(1999) No. 12B in press, pp ?-?). Organic materials are excited when carrier electrons or holes injected by an electric field are recombined, and emit light when they fall down to a ground state. In this event, excited organic molecules take a singlet excited state of high energy (electrons exhibit reverse spin) and a triplet excited state of low energy (electrons exhibit normal spin). The luminescence is classified according to the duration of afterglow after the supply of excitation energy is stopped, and generally classified into fluorescence when the afterglow lasts for several nano seconds and phosphorescence when the afterglow lasts for several micro seconds. But this classification is not exact strictly. In the phosphorescence, light emission duration decreases in proportion to the elevation in ambient temperature. On the other hand, in the fluorescence, the duration of afterglow does not depend on the temperature and the afterglow process extremely rapid.

In recent studies on the organic EL elements, organic phosphorescent materials have increasingly drawn attention as materials for improving a light emission efficiency. Generally, the light emission process of phosphorescence involves excitation of molecules from a ground state to an excited state, and a subsequent non-irradiate transition from a singlet state to a triplet state, referred to as intersystem crossing. The phosphorescence refers to the luminescence from the triplet state to the ground state, while the afterglow corresponding to a transition of the triplet state to the singlet state and to the ground state is referred to as delay fluorescence. In this manner, the spectrum of organic phosphorescence is always different from the spectrum of general fluorescence. This is because the two cases differ in the light emitting state (the singlet state and the triplet state) and common in the final ground state. For example, in anthracene, phosphorescence is red in a range of 670 to 800 nm, and fluorescence is blue in a range of 470 to 480 nm.

It is anticipated that a high light emission efficiency is achieved when the singlet state and the triplet state of the organic phosphorescent material are utilized in a light emitting layer of an organic EL element. The triplet is utilized because it is thought that excitons of singlet and triplet excited states are produced at a ratio of 1:3 due to a difference in the spin multiplicity when electrons and holes are re-combined in the organic EL element, so that the achievement of a light emission efficiency three times higher than that of a fluorescence-based element is expected.

However, the organic phosphorescent material has a problem that the light emission efficiency is reduced when a temperature rise in a driven organic EL element causes a reduction in a phosphorescence lasting time of the phosphorescent material in a light emitting layer. While a light emitting layer of an organic phosphorescent material is effectively provided for increasing the light emission efficiency of the organic EL element, the lifetime of the element must be further extended. Therefore, a need exists for an organic EL element, which exhibits a high light emission efficiency, capable of continuously emitting light at a high luminance with a less current.

### OBJECT AND SUMMARY OF THE INVENTION

It is an object of the present invention to provide an organic EL element which provides for extension of lifetime.

An organic EL element according to the present invention has an anode, a hole injecting layer made of an organic compound a light emitting layer made of an organic compound, an electron transport layer made of an organic compound and a cathode, which are laminated in order,

wherein the light emitting layer includes a phosphorescent material, and

wherein the hole injecting layer is made of a porphyrin compound represented by the following structural formula (1) or (2):

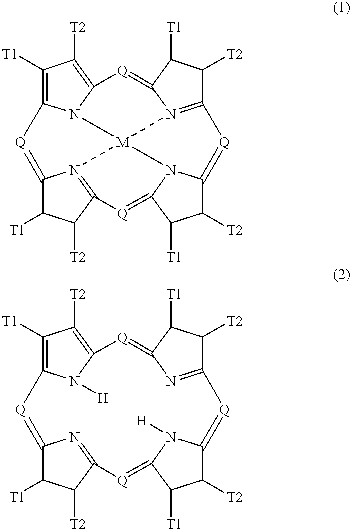

wherein Q is —N=or —C(R)=; M is a metal, a metal oxide or a metal halide; R is hydrogen, alkyl, aralkyl, aryl or alkaryl; Ti and T2 each represent an unsaturated six-membered ring which includes hydrogen or a substituent of alkyl or halogen and is completed together therewith, wherein the six-membered ring is formed of carbon, sulfur and nitrogen cyclic atoms, and an alkyl portion includes one to six carbon atoms.

In one aspect of the organic EL element according to the invention, the element further includes one or more layers made of a material including an organic compound and having a hole transport capability, disposed between said hole injecting layer and said light emitting layer.

In another aspect of the organic EL element according to the invention, the element further includes one or more mixed layers made of a plurality of materials including an organic compound and having a hole transport capability, disposed between said hole injecting layer and said light emitting layer.

In a further aspect of the organic EL element according to the invention, the element further includes an electron injecting layer disposed between said cathode and said electron transport layer.

In a still further aspect of the organic EL element according to the invention, the element further includes a hole blocking layer made of an organic compound between said light emitting layer and said electron transport layer.

In another aspect of the organic EL element according to the invention, said light emitting layer includes an electron transport material having an ionization potential smaller than said hole blocking layer.

### BRIEF DESCRIPTION OF THE DRAWINGS

FIGS. 1 through 4 are diagrams each illustrating the structure of an organic EL element; and

FIG. 5 is a graph showing a luminance characteristic and a voltage characteristic of an organic EL element according to the present invention.

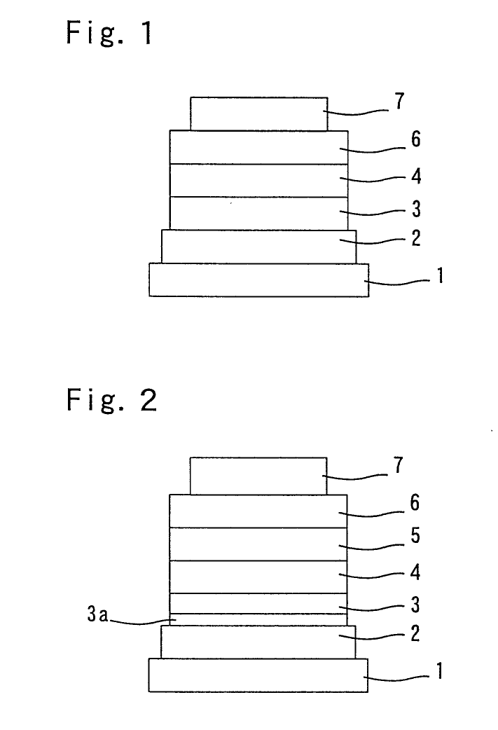

### DETAILED DESCRIPTION OF THE PREFERRED EMBODIMENT

An embodiment of the present invention will hereinafter be described with reference to the accompanying drawings.

As illustrated in FIG. 2, an organic EL element according to the present invention comprises a transparent anode 2; a hole injecting layer 3a made of a particular organic compound; a hole transport layer 3 made of an organic compound; a light emitting layer 4 made of an organic compound; a hole blocking layer 5 made of an organic compound; an electron transport layer 6 made of an organic compound; and a cathode 7 made of a metal, which are laminated in this order on a transparent substrate 1 such as glass.

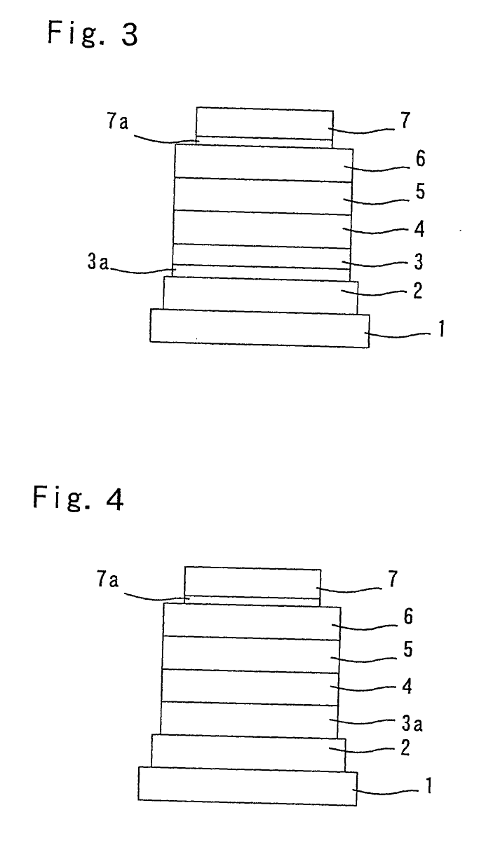

In addition to the foregoing structure, another organic EL element may have a structure which includes an electron injecting layer 7a laminated or deposited as a thin film between the electron transport layer 6 and the cathode 7, as illustrated in FIG. 3.

Alternatively, the hole transport layer 3 may be omitted from the organic EL element structures illustrated in FIGS. 2 and 3, provided that the light emitting layer 4 is made of a light emitting material having the hole transport capability. For example, as illustrated in FIG. 4, an organic EL element may have a structure comprised of an anode 2, a thermally stable organic hole injecting layer 3a, a light emitting layer 4 including an organic phosphorescent material, a hole blocking layer 5, an electron transport layer 6 and a cathode 7 deposited in this order on a substrate 1.

In the embodiment, used as the cathode 1 may be a metal which has a small work function, for example, lithium, barium, aluminum, magnesium, indium, silver, alloys thereof, or the like, and a thickness in a range of approximately 100 to 5,000 angstroms. Also, used as the anode 2 may be a conductive material which has a large work function, for example, indium tin oxide (hereinafter abbreviated as “ITO”) or the like, and a thickness in a range of approximately 300 to 3,000 angstroms, or gold of approximately 800 to 1,500 angstroms in thickness. It should be noted that when gold is used as an electrode material, the electrode is translucent. Either the cathode or the anode may be transparent or translucent.

In the embodiment, the hole injecting layer 3a made of a particular organic compound, laminated between the transparent anode 2 and the hole transport layer 3, is preferably made of a porphyrin compound. A preferred porphyrin compound may be a material represented by the above structural formula (1) or (2) Particularly preferred examples of effective porphyrin compounds are a phthalocyanine which does not hold a metal, and phthalocyanine which includes a metal. While a porphyrin compound generally and phthalocyanine particularly can contain a metal, the metal preferably has bivalent or more positive charges. Typically preferred metals are cobalt, magnesium, zinc, palladium, nickel, and particularly copper, lead and platinum.

Since a porphyrin compound is thermally stable and experiences a small change in film structure due to Jour heat generated while the element is driven, this results in a reduced change in the energy level difference between the transparent anode and the porphyrin compound hole injecting layer. Thus, an increase in voltage is reduced while the element is driven. Since the increase in voltage is suppressed, it is possible to suppress a reduction in a light emission lasting time of the phosphorescence caused by a temperature rise of the phosphorescent material in the light emitting layer.

Specifically, a porphyrin compound for the hole injecting layer 3a is, for example, copper phthalocyanine represented by the following chemical formula (3), so-called CuPc:

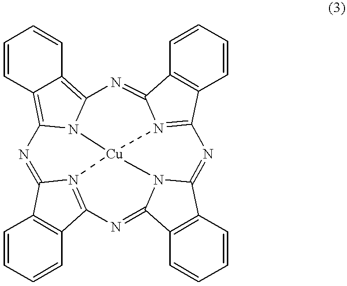

Also, the porphyrin compound for the hole injecting layer 3a includes the following materials:

porphine;

1,10,15,20-tetraphenyl-21H,23H-porphine copper (II);

1,10,15,20-tetraphenyl-21H,23H-porphine zinc (II);

5,10,15,20-tetrakis(pentafluorophenyl)-21H,23H-porphine; silicon phthalocyanine oxide;

aluminum phthalocyanine chloride;

phthalocyanine (without metal);

dilithium phthalocyanine;

copper tetramethyl phthalocyanine;

chromium phthalocyanine;

zinc phthalocyanine;

lead phthalocyanine;

titanium phthalocyanine oxide;

magnesium phthalocyanine;

copper octamethyl phthalocyanine; and

chromium phthalocyanine fluoride.

In the embodiment, an organic phosphorescent material, which is a component included in the light emitting layer 4 is, for example, 2,3,7,8,12,13,17,18-octaethyl-21H,23H-porphyrin platinum (II), tris(2-phenylpyridine) iridium (hereinafter referred to as “Ir(PPY)3”), or the like. Ir(PPY)3 is represented by the following chemical formula (4):

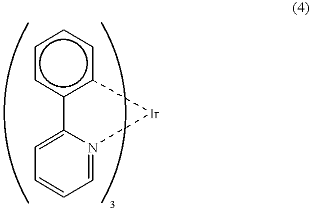

In the embodiment, a material for the hole blocking layer 5 laminated between the light emitting layer 4 and the electron transport layer 6 is an electron transport material having the electron transport capability, e.g., selected from materials represented by the following chemical formulae (5) to (26). Alternatively, the hole blocking layer 5 may be a mixed layer made of two or more kinds of electron transport materials mixed by coevaporation or the like, and deposited. Electron transport materials having the electron transport capability may be selected from materials represented by the following chemical formulae. An electron transport material of the hole blocking layer is selected to be a material whose ionization potential is larger than the ionization potential of the light emitting layer.

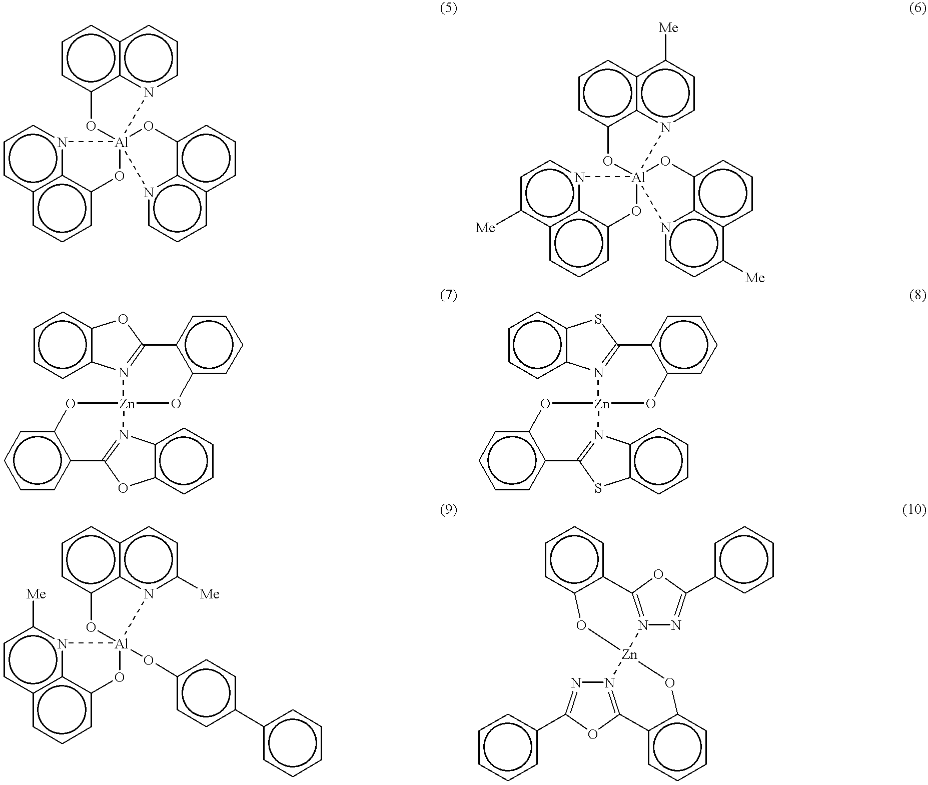

In the embodiment, the component contained in the light emitting layer is a hole transport material having the hole transport capability represented by the following formulae (27) to (46), for example.

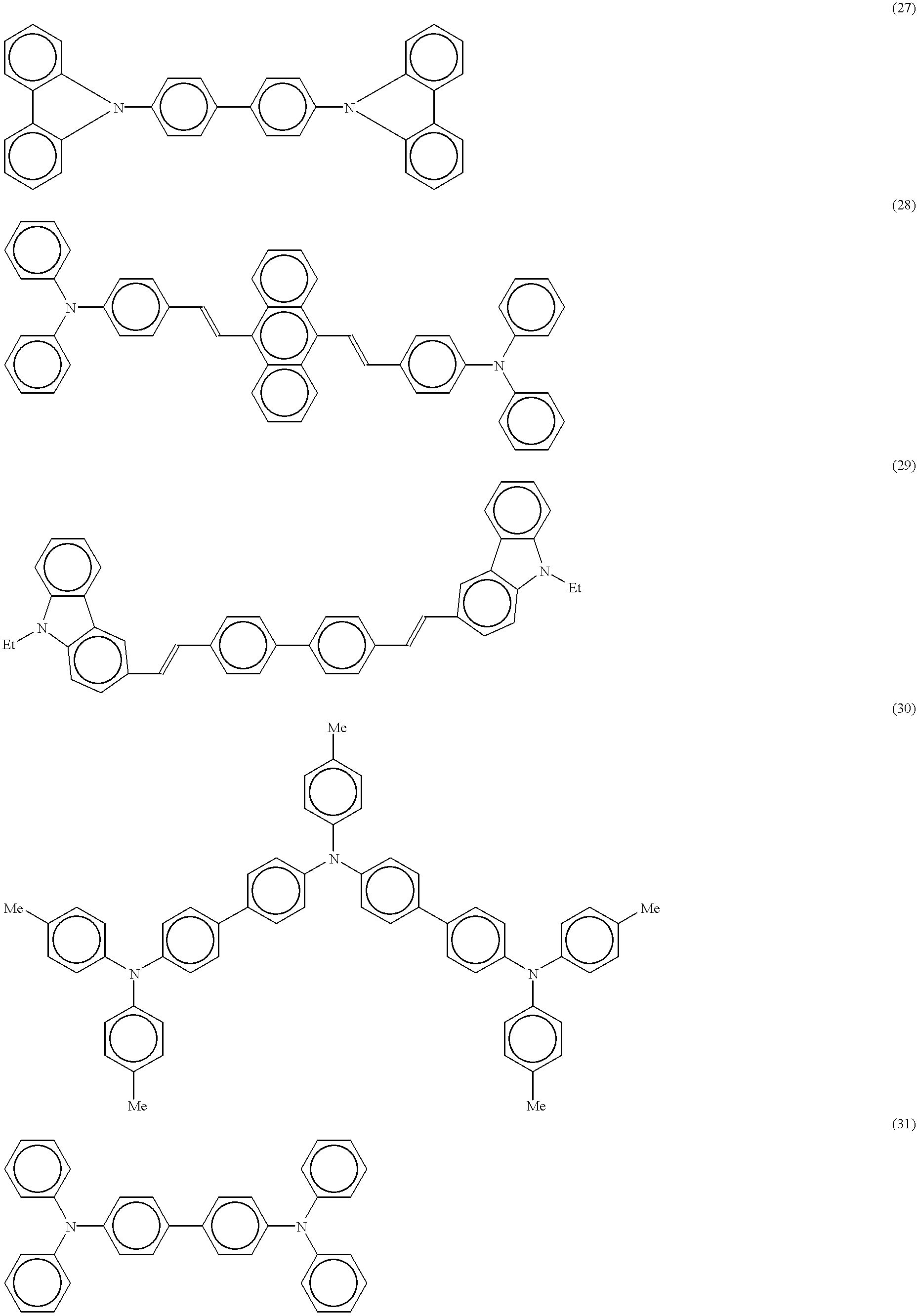

In the foregoing chemical formulae, Me represents a methyl group; Et, an ethyl group; Bu, a butyl group; and t-Bu, a tertiary class butyl group. The light emitting layer 4 may contain materials other than those shown in the foregoing chemical formulae. Also, the light emitting layer may be doped with a fluorescent material or a phosphorescent material having a high fluorescence quantum efficiency.

In the embodiment, a material for the hole transport layer 3 may be selected, for example, from materials having the hole transport capability as represented by the foregoing chemical formulae (27) to (46). In addition, the hole transport layer disposed on the hole injecting layer may be formed by coevaporation as a mixed layer comprised of a plurality of materials having the hole transport capability, made of organic compounds, and additionally one or more mixed layers may be provided. In this way, one or more layers made of an organic compound having the hole transport capability can be disposed between the hole injecting layer and the light emitting layer as a hole injecting layer or a hole transport layer.

An organic EL element was specifically made for evaluating its characteristics.

### EXAMPLE

The respective thin films were laminated on a glass substrate formed with an anode made of ITO having a thickness of 110 nm by a vacuum deposition method at the degree of vacuum of 5.0×10⁻⁶ Torr.

First, CuPc represented by the above formula (3) was formed in a thickness of 25 nm on the ITO as a hole injecting layer at a deposition rate of 3 Å/sec.

Next, 4,4′-bis[N-(1-naphthyl)-N-phenylamino]-biphenyl (so-called NPB) represented by the above formula (44) was formed on the hole injecting layer as a hole transport layer in a thickness of 35 nm at a deposition rate of 3 Å/sec.

Next, 4,4′-N,N′-dicarbasol-biphenyl (hereinafter abbreviated as “CBP”) represented by the above formula (27) and Ir(PPY)3 represented by the above formula (4) were coevaporated from different evaporation sources on the hole transport layer to form a light emitting layer of 30 nm in thickness. In this event, the concentration of Ir(PPY)3 in the light emitting layer was 6.5 wt %. The CBP was deposited at a deposition rate of 5 Å/sec.

Next, on the light emitting layer, 2, 9-dimethyl4,7-diphenyl-1, 10-phenanthroline (so-called BCP) represented by the above formula (18) was vapor deposited to form a hole blocking layer of 10 nm in thickness.

Subsequently, on the hole blocking layer, tris-(8-hyroxyquinolinealuminum) (so-called Alq3) represented by the above formula (5) was deposited as an electron transport layer in a thickness of 40 nm at a deposition rate of 3 Å/sec.

Further, on the electron transport layer, lithium oxide (Li₂O) was deposited as an electron injecting layer in a thickness of 5 Å at a deposition rate of 0.1 Å/sec, and aluminum (Al) was laminated on the electron injecting layer as an electrode in a thickness of 100 nm at a rate of 10 Å/sec to complete an organic light emitting element.

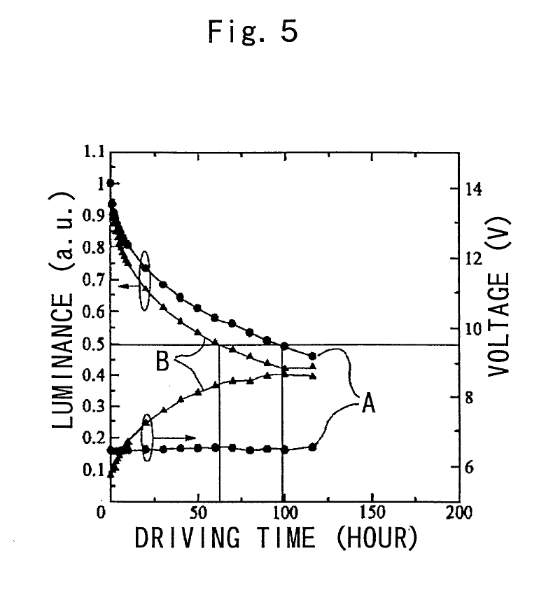

The thus obtained element emitted light from Ir(PPY)3. When the element created as described was driven with a regulated current of 0.1 mA/mm², an initial luminance Lo was equal to 976.2 cd/m². The element exhibited the luminance characteristic with time and voltage characteristic indicated by a set of curves A in FIG. 5.

### Comparative Example

An element of Comparative Example 1 was created in a similar manner to Example except that no hole injecting layer was provided and the NPB hole transport layer was formed in a thickness of 60 nm. The element was measured similarly to Example, and exhibited a luminance characteristic with time (Lo=948.1 cd/m²) and voltage characteristic as indicated by a set of curves B in FIG. 5.

As is apparent from FIG. 5, the element of Example significantly suppressed an increase in voltage while it was driven, and improved the half-life of luminance, as compared with Comparative Example.

As described above, according to the present invention, since a thermally stable porphyrin compound is used for a hole injecting layer in an organic EL element including a phosphorescent material in an organic light emitting layer, a reduction in the light emitting efficiency can be suppressed during driving of the element, thereby providing an organic EL element which can emit light for a long time period.

It is understood that the foregoing description and accompanying drawings set forth the preferred embodiments of the invention at the present time. Various modifications, additions and alternative designs will, of course, become apparent to those skilled in the art in light of the foregoing teachings without departing from the spirit and scope of the disclosed invention. Thus, it should be appreciated that the invention is not limited to the disclosed embodiments but may be practiced within the full scope of the appended claims.

This application is based on a Japanese Patent Application No.2000-130693 which is hereby incorporated by reference.

What is claimed is:

1. An organic electroluminescence element having a laminate of an anode, a hole injecting layer made of an organic compound and laminated, a light emitting layer made of an organic compound, an electron transport layer made of an organic compound, and a cathode, wherein said light emitting layer includes a phosphorescent material; and said hole injecting layer is made of a porphyrin compound represented by the following structural formula (1) or (2): 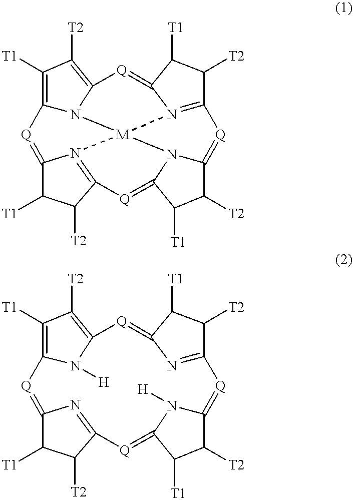
wherein Q is —N= or —C(R)=; M is a metal, a metal oxide or a metal halide; R is hydrogen, alkyl, aralkyl, aryl or alkaryl; T1 and T2 each represent an unsaturated six-membered ring which includes hydrogen or a substituent of alkyl or halogen and is completed together therewith, wherein said six-membered ring is formed of carbon, sulfur and nitrogen cyclic atoms, and an alkyl portion includes one to six carbon atoms.

2. An organic electroluminescence element according to claim 1, further comprising one or more layers made of a material including an organic compound and having a hole transport capability, disposed between said hole injecting layer and said light emitting layer.

3. An organic electroluminescence element according to claim 1 , further comprising one or more mixed layers made of a plurality of materials including an organic compound and having a hole transport capability, disposed between said hole injecting layer and said light emitting layer.

4. An organic electroluminescence element according to claim 1, further comprising an electron injecting layer disposed between said cathode and said electron transport layer.

5. An organic electroluminescence element according to claim 1 further comprising a hole blocking layer made of an organic compound between said light emitting layer and said electron transport layer.

6. An organic electroluminescence element according to claim 5, wherein said light emitting layer includes an electron transport material having an ionization potential smaller than said hole blocking layer.
